(19) United States
(12) Patent Application Publication
(10) Pub. No.: US 2009/0170236 A1
(43) Pub. Date: Jul. 2, 2009

(54) MANUFACTURING METHOD OF IMAGE SENSOR

(76) Inventor: Chung-Kyung Jung, Gangnam-gu (KR)

Correspondence Address: SHERR & VAUGHN, PLLC, 620 HERNDON PARKWAY, SUITE 200, HERNDON, VA, 20170, US

(21) Appl. No.: 12/344,500

(22) Filed: Dec. 27, 2008

(30) Foreign Application Priority Data
Dec. 27, 2007 (KR) 10-2007-0139444

(51) Int. Cl. H01L 21/04

(52) U.S. Cl. 438/98; 438/669; 257/E21.04

(57) ABSTRACT

A manufacturing method of an image sensor includes forming lower electrodes over a semiconductor substrate having metal wires and an interlayer insulating film formed thereover; removing a photoresist polymer produced by the formation of the lower electrodes by performing a primary treatment using a first substance; and then removing an electrode polymer produced by the formation of the lower electrodes by performing a secondary treatment using a second substance.

The present application claims priority under 35 U.S.C. §119 to Korean Patent Application No. 10-2007-0139444 (filed on Dec. 27, 2007), which is hereby incorporated by reference in its entirety.

### BACKGROUND

An image sensor is a semiconductor device that converts an optical image to an electrical signal. Image sensors can be largely classified as a charge coupled device (CCD) image sensor or a CMOS (Complementary Metal Oxide Silicon) image sensor (CIS). The CMOS image sensor has photodiodes and MOS transistors formed in unit pixels to sequentially detect electrical signals of each unit pixel by a switching method, thus realizing images. Such a CMOS image sensor has a structure in which a photodiode region converting a light signal into an electric signal is arranged on a semiconductor substrate, in parallel to a transistor processing the electric signal. According to a lateral CMOS image sensor, which is one of various types of CMOS image sensors, a photodiode and a transistor are formed next to each other on a substrate. This structure, however, requires an additional area for forming the photodiode.

### SUMMARY

Embodiments relate to a manufacturing method of an image sensor which provides a vertical integration of a CMOS circuit and a photodiode.

Embodiments relate to a manufacturing method of an image sensor which maximizes resolution and sensitivity.

Embodiments relate to a manufacturing method of an image sensor which employs a vertical type photodiode and prevents a crosstalk and a noise phenomenon.

Embodiments relate to a method that may include at least one of the following: forming an interlayer insulating film having metal wires over a semiconductor substrate; forming a lower electrode layer over the semiconductor substrate including the metal wires and the interlayer insulating film; forming a photoresist pattern over the lower electrode layer exposing a portion of the interlayer insulating film; forming lower electrodes electrically connected to the metal wires by an etching process using the photoresist pattern as a mask; removing a photoresist polymer produced by the formation of the lower electrodes performing a primary treatment using a first substance; and then removing an electrode polymer produced by the formation of the lower electrodes by performing a secondary treatment using a second substance.

Embodiments relate to a method that may include at least one of the following: forming an interlayer insulating film having metal wires over a semiconductor substrate; forming a metal layer over the semiconductor substrate including the metal wires and the interlayer insulating film; forming a photoresist pattern over the lower electrode layer; forming lower electrodes spaced apart and electrically connected to the metal wires by performing an etching process on the metal layer using the photoresist pattern as a mask; and then removing a photoresist polymer and an electrode polymer generated by the formation of the lower electrodes by a zeta potential using at least one of an acidic solution and an alkaline solution.

Embodiments relate to a method that may include at least one of the following: forming one of an oxide film and a nitride film having metal wires therein over a semiconductor substrate; forming a metal layer over the semiconductor substrate including the metal wires and the one of the oxide film and the nitride film; forming a photoresist pattern over the metal layer exposing a portion of the one of the oxide film and the nitride film; forming lower electrodes spaced apart over the one of the oxide film and the nitride film and electrically connected to the metal wires by performing an etching process on the metal layer using the photoresist pattern as a mask; and then performing first cleaning process using a first cleaning substance to remove a photoresist polymer produced by the formation of the lower electrodes; performing second cleaning process using a second cleaning substance different than the first cleaning substance to remove an electrode polymer produced by the formation of the lower electrodes; and then forming a photodiode over and contacting the exposed portion of the of the oxide film and the nitride film and also the lower electrodes.

### DRAWINGS

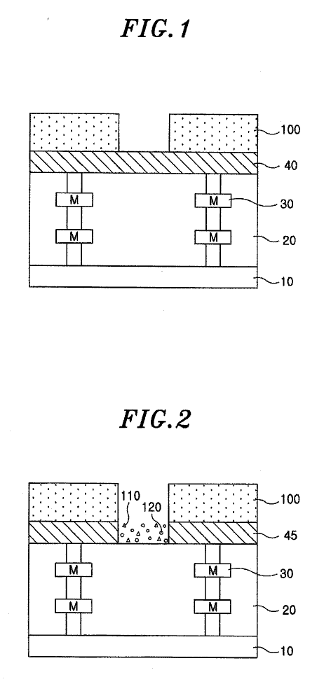

Example FIGS. 1 to 11 show cross-sectional views for explaining a method of manufacturing an image sensor in accordance with embodiments.

### DESCRIPTION

It will be appreciated to those skilled in the art that the thickness or size of each layer in the drawings is exaggerated, omitted, or roughly shown for convenience of explanation and clarity. Also, the sizes of respective elements do not always reflect actual sizes.

Referring to example FIG. 1, a method of manufacturing an image sensor in accordance with embodiments includes an interlayer insulating film 20 having metal wires 30 formed on and/or over a semiconductor substrate 10. A device isolation film defining an active region and a field region may also be formed in the semiconductor substrate 10. In the active region of the semiconductor substrate 10, transistors which are electrically connected to photodiodes to convert a received light signal into an electric signal may be formed in unit pixels. For example, the transistors may be any one of 3Tr, 4Tr, and 5Tr. The interlayer insulating film 20 and the metal wires 30 for connection to a power line or a signal line are formed on and/or over the semiconductor substrate 10. The interlayer insulating film 20 may be formed of a plurality of layers. The interlayer insulating film 20 may be formed of a nitride film or an oxide film.

The metal wires 30 pass through the interlayer insulating film 20 and include metal wires M and plugs. The metal wires 30 serve to deliver electrons produced by photodiodes to transistors underneath them. The metal wires 30 may be formed so as to be connected to an impurity doped region formed underneath the semiconductor substrate 10 in unit pixels. For instance, the metal wires 30 can be made of a variety of conductive materials including metals, alloys, or salicide, examples of which include, but are not limited to, aluminum, copper, cobalt, and tungsten. A lower electrode layer 40 is formed on and/or over the interlayer insulating film 20 including the metal wires 30. For example, the lower electrode layer 40 may be made of metal such as chromium (Cr). The lower electrode layer 40 is formed over the entire part of interlayer insulating film 20 so as to be electrically connected to the metal wires 30. A photoresist pattern 100 is formed on and/or over the lower electrode layer 40 by coating a photoresist film on and/or over the lower electrode layer 40 by a spin process, and then carrying out an exposing and developing process using an exposure mask. The photoresist pattern 100 can cover the lower electrode layer 40 corresponding to the metal wires 30, while exposing the other region.

Referring to example example FIG. 2, lower electrodes 45 are then formed spaced apart on and/or over the interlayer insulating film 20 in unit pixels so as to be electrically connected to the metal wires 30, respectively. The lower electrodes 45 are isolated from each other, so that they can be formed in unit pixels depending on the position of the metal wires 30. The lower electrodes 45 can be formed by wet etching the lower electrode layer 40 using the photoresist pattern 100 as an etch mask. For instance, the lower electrode 45 may be formed by a wet etching process using ceric ammonium nitrate (CAN). Therefore, the lower electrodes 45 can be formed on and/or over the interlayer insulating film 20 and electrically connected to the metal wires 30. Also, the lower electrodes 45 can be spaced apart to selectively expose the interlayer insulating film 20. Especially, the broader the lower electrode 45 is formed, the greater the amount of photocharge may be accumulated on the photodiodes.

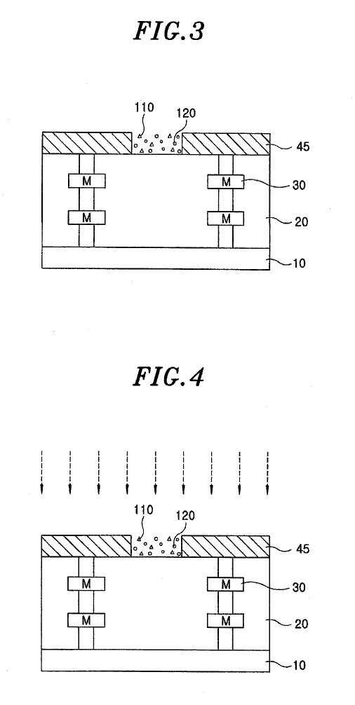

Referring to example FIG. 3, the photoresist pattern 100 can be removed by ashing. Polymers produced when the photoresist pattern 100 is removed may adhere to the side walls of the lower electrodes 45 to prevent the lower electrodes 45 from being damaged by the ashing process. Meaning, when the lower electrodes 45 are etched using the photoresist pattern 100 as an etch mask, residuals of the photoresist pattern 100 and polymers such as chrome residuals (CrₓO_{y}N_{z}, where x, y and z are natural numerals) used as the lower electrodes 45 remain on and/or over the semiconductor substrate 10. For instance, the residuals of the photoresist pattern 100 are referred to as a first polymer 110, and the residuals of the lower electrodes 45 are referred to as a second polymer 120. When the first and the second polymers 110 and 120 remain on and/or over the semiconductor substrate 10, electrical characteristics of the device can be degraded. In particular, they interfere with the movement of photoelectrons produced from the photodiodes formed on and/or over the lower electrodes 45, thus deteriorating image features. In general, the first and the second polymers 110 and 120 can be removed by exposing them to Cl₂ and O₂ gas. However, the lower electrodes 45 made of chromium (Cr) react with the O₂ gas and thus, may become corrosive. In order to prevent such a problem, embodiments remove the first polymer 100, followed by removing the second polymer 120.

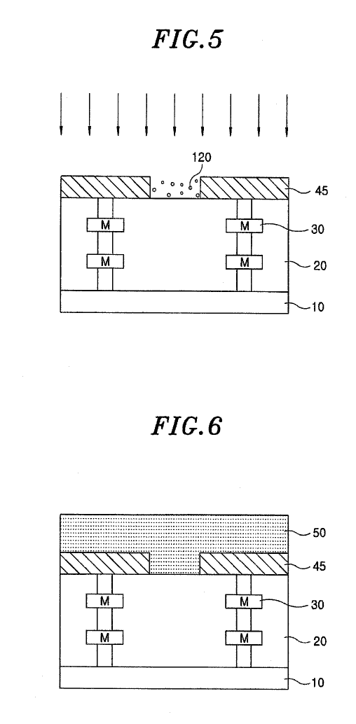

Referring to example FIG. 4, a primary treatment is performed on the semiconductor substrate 10 to remove the first polymer 110. Meaning, the primary treatment is a removal process of the photoresist residuals. The primary treatment is a wet treatment using H₂SO₄. This primary treatment using H₂SO₄ continues for a time period in a range between approximately 5-30 minutes at a temperature in a range between approximately 70-90° C. Accordingly, the first polymer 110 can be removed from the semiconductor substrate 10. The photoresist pattern 100 can also be removed simultaneously. Typically, the removal of the photoresist is done by a mixture of H₂SO₄ and H₂O₂, however, H₂O₂ can corrode chromium. For this reason, embodiments use only H₂SO₄ to remove the photoresist residual without damaging the lower electrodes 45.

Referring to example FIG. 5, the secondary treatment on the semiconductor substrate 10 removes the second polymer 120, i.e., the chromium residuals. The secondary treatment is a wet treatment using trimethyl-oxyethyl-ammonium-hydroxide (TMH). The TMH may be expressed by the chemical formula CH₃O₃N(CH₂CH₂OH)OH. The secondary treatment using TMH continues for a time period in a range between approximately 5-20 minutes at a temperature in a range between approximately 60-75° C. As a result, the second polymer 120 can be removed from the semiconductor substrate 10. The first and the second polymers 110 and 120, i.e. the photoresist and chromium residuals, are removed from the semiconductor substrate 10 through the primary and the secondary treatments using the above-described chemicals. In particular, since both the primary and the secondary treatments are wet treatments using chemicals, the lower electrodes 45 made of chrome are protected against corrosion. Therefore, polymer-free lower electrodes 45 can be formed on and/or over the semiconductor substrate 10. As a result, the photoresist and chromium residuals that stimulate the degradation of optical and electrical characteristics of the image sensor are removed from the semiconductor substrate 10, and thus, reliability of the device can be maximized.

Referring to example FIG. 6, a photodiode 50 is formed on and/or over the semiconductor substrate 10 including the interlayer insulating layer 20 and the lower electrodes 45. For example, the photodiode 50 may be formed by implanting n-type and p-type dopants into a crystalline semiconductor layer and then adhering the crystalline semiconductor layer to the semiconductor substrate 10 including the interlayer insulating layer 20 and the lower electrodes 45. Alternatively, the photodiode 50 may be formed by depositing amorphous silicon on and/or over the interlayer insulating film 20 including the interlayer insulating layer 20 and the lower electrodes 45. In this manner, when the photodiode 50 is formed, photoelectrons produced from the photodiode 50 are transferred to a unit pixel circuitry through the lower electrodes 45. In particular, in accordance with embodiments, since surfaces of the lower electrodes 45 where the photoelectrons are accumulated are already clean from undesirable impurities, optical characteristics of the image sensor can be maximized. A color filter and a microlens may be formed on and/or over the photodiode 50. In accordance with embodiments, the vertical integration can be achieved by having photodiodes formed on and/or over the semiconductor substrate having the metal wires. In addition, the vertical integration of photodiodes can make fill factors close as 100%. Moreover, an additional on-chip circuitry that can be integrated and thus, maximize performance of the image sensor. Miniaturization of the device can be achieved, overall manufacturing costs can be reduced and device defects can be prevented by removing undesirable impurities such as polymers produced by the formation of the lower electrodes.

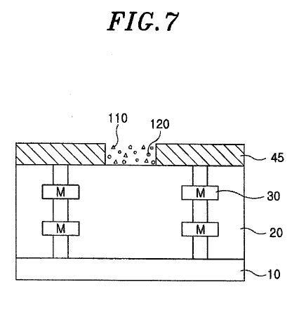

Referring to example FIG. 7, a method of manufacturing an image sensor in accordance with embodiments can include forming an interlayer insulating film 20 having metal wires 30 on and/or over a semiconductor substrate 10. Next, lower electrodes 45 are formed in unit pixels so as to be electrically connected to the metal wires 30 on and/or over the interlayer insulating film 20, respectively. The semiconductor substrate 10, the metal wires 30, the interlayer insulating film 20, and the lower electrodes 45 are same as those illustrated and described above with reference to example FIGS. 1 and 2, and, therefore, the description thereof will be omitted here for simplicity. The lower electrodes 45 may be formed by a wet etching process using ceric ammonium nitrate (CAN) and employing a photoresist pattern 100 as an etch mask, as depicted in example FIG. 2.

As shown in example FIG. 7, the lower electrodes 45 may be formed on and/or over the interlayer insulating film 20 so as to be electrically connected to the metal wires 30, respectively. Also, the lower electrodes 45 can be spaced apart to selectively expose the interlayer insulating film 20. In particular, the broader the lower electrode 45 is, the greater the amount of photocharge may be accumulated on the photodiodes. In this way, when the lower electrodes 45 are etched by using the photoresist pattern 100 as an etch mask, residuals of the photoresist pattern 100 and polymers such as chromium residual (CrₓO_{y}N_{z}, where x, y and z are natural numerals) used as the lower electrodes 45 stay on and/or over the semiconductor substrate 10. For instance, the residuals of the photoresist pattern are referred to as a first polymer 110, and the residuals of the lower electrodes 45 are referred to as a second polymer 120. When the first and the second polymers 110 and 120 remain on and/or over the semiconductor substrate 10, electrical characteristics of the device can be deteriorated. In particular, the polymers interfere with the movement of photoelectrons produced from the photodiodes formed on and/or over the lower electrodes 45, impairing image features. In accordance with embodiments, zeta potential can be used to remove the first and the second polymers 110 and 120.

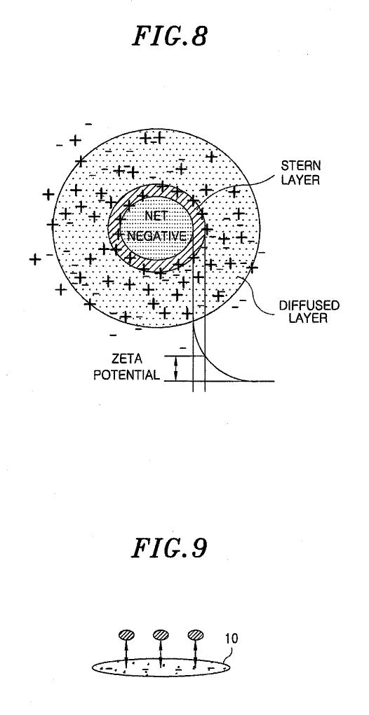

Zeta potential will be explained with reference to example FIG. 8. Typically, a substance has its own electric charge. A group of fine, distinctive particles that are dispersed or floating in a solution is called a colloid. The colloid carries electric charges when it is present in a medium of an aqueous solution, and most of the electric charges are resulted from selective ion adsorption from the aqueous solution. As shown in example FIG. 8, a colloidal substance has a negative charge. Since all colloids have a negative electrostatic charge, they tend to push against one another, generating a repulsion force, which may be a zeta potential. Meaning, when negatively charged particles are present in an aqueous solution, they are bonded to cations around them, which are called a Stern layer. Other cations are further gathered because of an attractive force of the negatively charged particles around the Stern layer. These cations are pushed away by the repulsion force from other cations that try to approach the Stern layer and the colloid. This dynamic equilibrium allows a diffuse layer with a higher concentration of cations than that of anions to be formed around the Stem layer. The concentration of cations around the Stem layer stays high near the particle surfaces, but it gradually decreases as the distance increases and eventually reaches an equilibrium state with a bulk solution. The boundary between the Stem layer and the diffuse layer is called a shear boundary, and a potential difference between the shear boundary and the bulk solution is called a zeta potential. The zeta potential has at least the following characteristics. First, the higher the pH value, the zeta potential becomes stronger in negative charge, while the lower the pH value, the zeta potential becomes stronger in positive charge. Second, substances such as metals, oxides, nitrides, etc. generally have a positive charge. Third, colloids reach a stable equilibrium state if the zeta potential increases, while colloids tend to cohere otherwise.

As shown in example FIG. 9, in order to make use of the zeta potential having the above-described characteristics, the first and the second polymers 110 and 120, the lower electrodes 45, and the interlayer insulating film 20 should be equal in their natures to create a repulsion force. The first polymer 110 (i.e., the photoresist residual) and the second polymer 120 (i.e., the chromium residual CrₓO_{y}N_{z}) have a negative charge. Meanwhile, the lower electrodes 45 are formed of chromium and the interlayer insulating film 20 is formed of an oxide film or a nitride film, so that they have a positive charge. Therefore, the interlayer insulating film 20 and the lower electrodes 45 undergo the pre-processing in a high-pH solution (i.e. a base solution) and then the post-processing using a scrubber. Meaning, a base solution with a pH value in a range between approximately 7 and 14 is used for the preprocessing of the interlayer insulation film 20 having the lower electrodes 45. For example, the base solution may be an alkaline solution having CₓH_{y}H_{z}—OH (where x, y, and z are natural numbers). Since the base solution has a negative charge, the first and the second polymers 110 and 120, when they are pre-processed with the base solution, are lifted off from the surface of the interlayer insulating film 20.

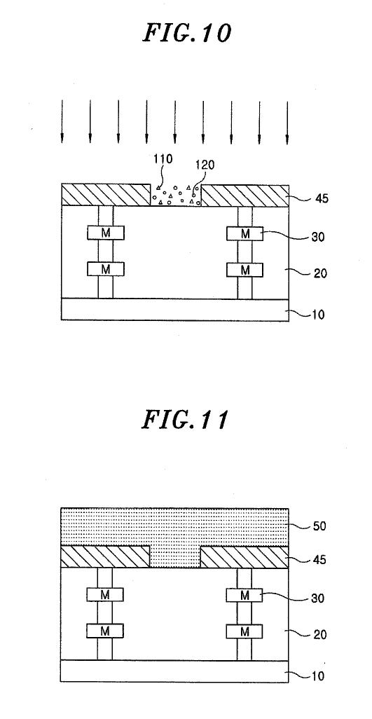

Referring to example FIG. 10, when a scrubber, particularly a MHz scrubber, is used for the post-processing, both the first and the second polymers 110 and 120 can be removed. For instance, the combined use of deionized water (DIW) and CO₂ in the scrubber process may remove all remaining polymers on and/or over the semiconductor substrate 10. Alternatively, the interlayer insulating film 20 and the lower electrodes 45 may go through the pre-processing in a low-pH solution (i.e. an acidic solution) and then the post-processing using a scrubber. Particularly, an acidic solution with a pH value in a range between approximately 1 and 6 is used for the pre-processing of the interlayer insulating film 20 having the lower electrodes 45. For example, the acidic solution may be any acidic solution having MₓC_{y}—H (where x and y are natural numbers). The acidic solution has the nature of a positive charge, and thus, the first and the second polymers 110 and 120, when they are pre-processed with the acidic solution, can be lifted off from the surface of the interlayer insulating film 20. Next, when a scrubber, particularly a MHz scrubber is used for the post-processing, both the first and the second polymers 110 and 120 can be removed. For instance, the combined use of DIW and CO₂ in the scrubber process can remove all remaining polymers on the semiconductor substrate 10. Thus, polymer-free lower electrodes 45 can be formed on and/or over the semiconductor substrate 10. As a result, the photoresist and chrome residuals that stimulate the degradation of optical and electrical characteristics of the image sensor are removed from the semiconductor substrate 10, reliability of the device can be maximized.

Referring to example FIG. 11, a photodiode 50 is formed on and/or over the semiconductor substrate 10 including the interlayer insulating layer 20 and the lower electrodes 45. For example, the photodiode 50 is formed by implanting n-type and p-type dopants into a crystalline semiconductor layer and then adhering the crystalline semiconductor layer on and/or over the semiconductor substrate 10 including the interlayer insulating layer 20 and the lower electrodes 45. Optionally, the photodiode 50 may be formed by depositing an amorphous silicon on and/or over the interlayer insulating film 20 and the lower electrodes 45. When the photodiode 50 is formed, photoelectrons produced from the photodiode 50 are transferred to a unit pixel circuitry through the lower electrodes 45. In accordance with embodiments, since surfaces of the lower electrodes 45 where the photoelectrons are accumulated have already become clean, optical characteristics of the image sensor can be improved. A color filter and a microlens may be formed on the photodiode 50.

In accordance with embodiments, the vertical integration can be achieved by forming photodiodes on and/or over a semiconductor substrate having metal wires. In addition, the vertical integration of photodiodes can make fill factors close to 100%. Moreover, an additional on-chip circuitry that can be integrated can maximize the performance of the image sensor, and further achieve miniaturization of the device and reduce manufacturing costs. Further, the lower electrodes are not damaged because the polymers produced during the patterning of the lower electrodes are removed by the zeta potential. The vertical integration can also provide a higher sensitivity than other techniques, provided that a pixel size is the same. Also, each unit pixel may be provided with more complicated circuitry without a reduction in sensitivity. Moreover, photosensitivity of the image sensor can be maximized by increasing the surface area of a photodiode within a unit pixel. Additionally, image characteristics of the device can be maximized by removing polymers that may deteriorate the optical characteristics of photodiodes.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming an interlayer insulating film having metal wires over a semiconductor substrate;
forming a lower electrode layer over the semiconductor substrate including the metal wires and the interlayer insulating film;
forming a photoresist pattern over the lower electrode layer exposing a portion of the interlayer insulating film;
forming lower electrodes electrically connected to the metal wires by an etching process using the photoresist pattern as a mask;
removing a photoresist polymer produced by the formation of the lower electrodes by performing a primary treatment using a first substance; and then
removing an electrode polymer produced by the formation of the lower electrodes by performing a secondary treatment using a second substance.

2. The method of claim 1, further comprising, after removing the electrode polymer:
forming a photodiode over and contacting the exposed portion of the interlayer insulating film and also the lower electrodes.

3. The method of claim 1, wherein the lower electrodes comprise a chromium material.

4. The method of claim 3, wherein the electrode polymers comprise a chromium-based (CrₓO_{y}N_{z}) residual.

5. The method of claim 4, wherein the chromium-based residual comprises chromium oxynitride.

6. The method of claim 1, wherein the lower electrodes is formed by wet etching the lower electrode layer.

7. The method of claim 1, wherein the wet etching uses ceric ammonium nitrate.

8. The method of claim 1, wherein the primary treatment removes the photoresist polymer using sulfuric acid (H₂SO₄).

9. The method of claim 1, wherein the secondary treatment removes the electrode polymer using trimethyl-oxyethyl-ammonium-hydroxide.

10. A method comprising:
forming an interlayer insulating film having metal wires over a semiconductor substrate;
forming a metal layer over the semiconductor substrate including the metal wires and the interlayer insulating film;
forming a photoresist pattern over the lower electrode layer;
forming lower electrodes spaced apart and electrically connected to the metal wires by performing an etching process on the metal layer using the photoresist pattern as a mask; and then
removing a photoresist polymer and an electrode polymer generated by the formation of the lower electrodes by a zeta potential using at least one of an acidic solution and an alkaline solution.

11. The method of claim 10, wherein the interlayer insulating film and the lower electrodes have a positive charge and the photoresist and the electrode polymers have a negative charge.

12. The method of claim 11, wherein the acidic solution comprises a chemical containing MₓC_{y}—H.

13. The method of claim 11, wherein the alkaline solution comprises a chemical containing MₓH_{y}N_{z}—OH.

14. The method of claim 11, further comprising, after removing the polymers:
performing a scrubber process.

15. The method of claim 14, wherein the scrubber process is carried out in the presence of carbon dioxide CO₂ and de-ionized water.

16. The method of claim 11, wherein the metal layer comprises chromium.

17. A method comprising:
forming one of an oxide film and a nitride film having metal wires therein over a semiconductor substrate;
forming a metal layer over the semiconductor substrate including the metal wires and the one of the oxide film and the nitride film;
forming a photoresist pattern over the metal layer exposing a portion of the one of the oxide film and the nitride film;
forming lower electrodes spaced apart over the one of the oxide film and the nitride film and electrically connected to the metal wires by performing an etching process on the metal layer using the photoresist pattern as a mask; and then performing first cleaning process using a first cleaning substance to remove a photoresist polymer produced by the formation of the lower electrodes;
performing second cleaning process using a second cleaning substance different than the first cleaning substance to remove an electrode polymer produced by the formation of the lower electrodes; and then
forming a photodiode over and contacting the exposed portion of the of the oxide film and the nitride film and also the lower electrodes.

18. The method of claim 17, wherein the metal layer comprises chromium.

19. The method of claim 17, wherein the first cleaning substance comprises sulfuric acid (H₂SO₄).

20. The method of claim 17, wherein the second cleaning substance comprises trimethyl-oxyethyl-ammonium-hydroxide.
